(19) United States
(12) Patent Application Publication
(10) Pub. No.: US 2011/0210758 A1
(43) Pub. Date: Sep. 1, 2011

(54) VOLTAGE DETECTOR CIRCUIT

(75) Inventor: Longyue Zhang, Kanagawa (JP)

(73) Assignee: Renesas Electronics Corporation

(21) Appl. No.: 13/020,299

(22) Filed: Feb. 3, 2011

(30) Foreign Application Priority Data
Feb. 26, 2010 (JP) 2010-042168

(51) Int. Cl. G01R 27/08

(52) U.S. Cl. 324/705

(57) ABSTRACT

A voltage detector circuit of the present invention includes a power supply voltage monitor that generates a monitored voltage resulting from dividing a power supply voltage, which is supplied from a first terminal, based on a resistance ratio between first and second resistors coupled between first and second terminals, a power supply voltage rising ramp detector that generates a boost signal which is enabled, if the power supply voltage rises faster than a preset rapidity to trigger operation switching, a resistance switching circuit that makes a third resistor coupled in parallel with the first resistor and a fourth resistor coupled in parallel with the second resistor active during a period when the boost signal is enabled, and a comparator that compares the monitored voltage with a reference voltage, and that outputs a voltage detection signal.

### CROSS-REFERENCE TO RELATED APPLICATIONS

The disclosure of Japanese Patent Application No. 2010-42168 filed on Feb. 26, 2010 including the specification, drawings and abstract is incorporated herein by reference in its entirety.

### BACKGROUND

The present invention relates to a voltage detector circuit and particularly to a voltage detector circuit that detects a voltage level of a power supply voltage with a plurality of resistors having high resistance values.

Recently, semiconductor integrated circuits tend to consume more power, as the circuit size becomes larger. Consequently, in order to decrease the power consumption of a semiconductor integrated circuit, different power supply voltages are supplied to respective built-in circuit blocks in the semiconductor integrated circuit and power supply voltage control is performed on a per circuit block basis. For this reason, there is a voltage detector circuit to monitor a power supply voltage supplied in a semiconductor integrated circuit. The voltage detector circuit detects when a power supply voltage has exceeded a predetermined voltage. At this detection timing, a circuit block is triggered to start operation or reset. Because such a voltage detector circuit operates only at power-on time, it is desired that its power consumption is as small as possible.

So far, an example of a voltage detector circuit that detects a voltage level of a power supply voltage, while suppressing power consumption, is disclosed in Japanese Application Publication No. 2002-296306. A circuit diagram of the voltage detector circuit 100 disclosed in Japanese Application Publication No. 2002-296306 is shown in FIG. 6. As shown in FIG. 6, the voltage detector circuit 100 includes terminals 110, 111, resistive divider resistors 113, 114, 121, a reference voltage source 115, a comparator 120, and a buffer circuit 116.

A voltage of a battery 101 is input to the voltage detector circuit 100 via the terminals 110, 111. Then, the voltage detector circuit 100 divides the input voltage with the resistive divider resistors 113, 114 and generates a divided voltage Va. By the comparator 120, the divided voltage Va is compared to a reference voltage Vb generated by the reference voltage source 115 and a result of the comparison is output via the buffer circuit 115. That is, a voltage that inverts the output of the comparator 120 is Va=Vb. Given that a resistance value of the voltage divider resistor 113 is R1, a resistance value of the voltage divider resistor 114 is R2, and the voltage of the battery 101 is Vi, a detected voltage of the battery 101 is given by equation (1), according to Va=R2/(R1+R2)×V1=Vb.

Detected voltage=(R1+R2)/R2×Vb (1)

Specifically, when the voltage of the battery 101 is higher than a value given by equation (1), the output of the comparator 120 becomes a high level; whereas, when the voltage of the battery 101 is lower than the value given by equation (1), the output of the comparator 120 becomes a low level. That is, the voltage detector circuit 100 is able to detect whether the voltage of the battery 101 is higher or lower than the detected voltage, depending on whether the output of the comparator 120 is high level or low level. Here, in the voltage detector circuit 100, the comparator 120 is coupled to a terminal 121. Consumption current of the comparator 120 varies depending on a signal that is input from the terminal 121. The voltage detector circuit 100 is capable of reducing the detection response time by increasing the consumption current of the comparator 120, if the detection response time is of first importance.

### SUMMARY

However, in order to decrease the power consumption of the voltage detector circuit 100, there is a need for increasing the resistance values of the voltage divider resistors 113, 114. Then, use of the voltage divider resistors 113, 114 with high resistance values causes an increase in a time constant that is determined by parasitic capacitances of the voltage divider resistors 113, 114. In consequence, such time constant makes change of the divided voltage Va slower than change of the voltage V1. In the case of reducing the power consumption of the voltage detector circuit 100, it is impossible to detect the change of the voltage V1 earlier than a delay time determined by the time constant, which poses a problem that the voltage detector circuit is unable to respond to a rapid change of the voltage V1.

The present invention seeks to solve one or more of the above problems, or to improve upon those problems at least in part.

In one embodiment, a voltage detector circuit according to the present invention includes a power supply voltage monitor that is equipped with first and second resistors coupled between a first terminal and a second terminal, and that generates a monitored voltage resulting from dividing a power supply voltage, which is supplied from the first terminal, based on a resistance ratio between the first and second resistors, a power supply voltage rising ramp detector that monitors the rising rapidity of the power supply voltage, and that generates a boost signal which is enabled for a certain period, if the power supply voltage rises faster than a preset rapidity to trigger operation switching, a resistance switching circuit that is equipped with a third resistor which is coupled in parallel with the first resistor and a fourth resistor which is coupled in parallel with the second resistor, and that makes the third and fourth resistors active during a period when the boost signal is enabled, and a comparator that compares the monitored voltage with a reference voltage, and that outputs a voltage detection signal indicating that the power supply voltage has exceeded a predetermined voltage value.

According to the voltage detector circuit pertaining to the present invention, if the power supply voltage rising faster than the rapidity to trigger operation switching is detected by the power supply voltage rising ramp detector, the first resistor and the third resistor are coupled in parallel and the second resistor and the fourth resistor are coupled in parallel. In consequence, it is possible to decrease a time constant of a node at which the monitored voltage is generated. Meanwhile, in the voltage detector circuit pertaining to the present invention, when the boost signal is disabled, the third resistor and the fourth resistor are made inactive and power consumption attributed to the first and second resistors can be reduced.

According to the voltage detector circuit pertaining to the present invention, it is possible to detect a rapid change of power supply voltage in a short response time as well as to reduce power consumption.

### BRIEF DESCRIPTION OF THE DRAWINGS

The above and other purposes, advantages and features of the present invention will become more apparent from the following description of a certain embodiment taken in conjunction with the accompanying drawings in which:

FIG. 1 is a circuit diagram of a voltage detector circuit pertaining to a first embodiment;

FIG. 2 is a circuit diagram of a power supply voltage rising ramp detector circuit pertaining to the first embodiment;

FIG. 3 is a graph representing a difference in the rising time of a power supply voltage that is applied to the voltage detector circuit pertaining to the first embodiment;

FIG. 4 is a timing chart explaining how the voltage detector circuit pertaining to the first embodiment operates, when the power supply voltage rises steeply;

FIG. 5 is a timing chart explaining how the voltage detector circuit pertaining to the first embodiment operates, when the power supply voltage rises slowly; and

FIG. 6 is a circuit diagram of a voltage detector circuit pertaining to Japanese Application Publication No. 2002-296306.

### DETAILED DESCRIPTION

### First Embodiment

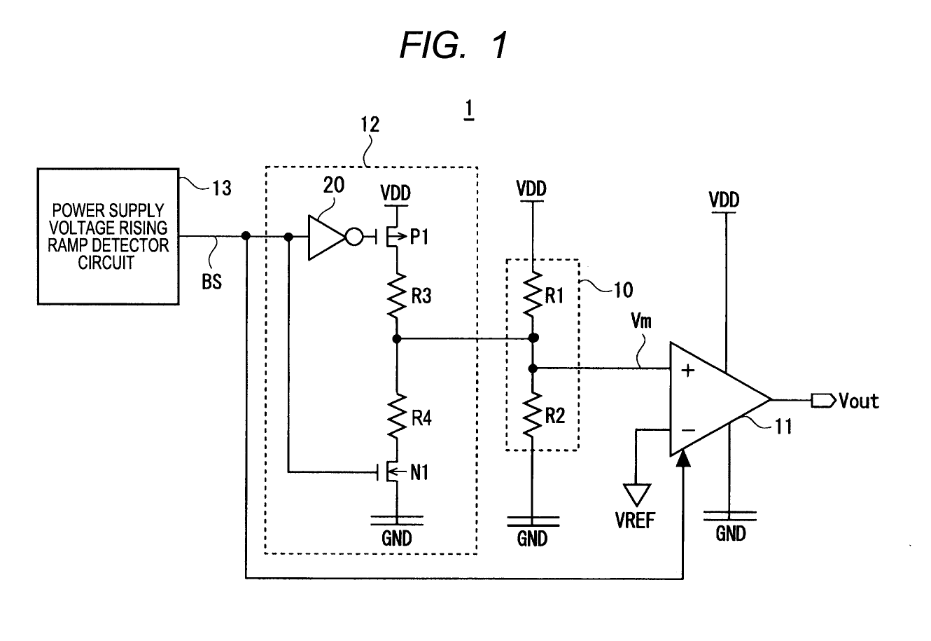

An embodiment of the present invention will be described hereinafter with reference to the drawings. A circuit diagram of a voltage detector circuit 1 pertaining to a first embodiment of the present invention is shown in FIG. 1. As shown in FIG. 1, the voltage detector circuit 1 includes a power supply voltage monitor circuit 10, a comparator 11, a resistance switching circuit 12, and a power supply voltage rising ramp detector circuit 13.

The power supply voltage monitor circuit 10 is equipped with a first resistor (e.g., resistor R1) and a second resistor (e.g., resistor R2) which are coupled between a first terminal (e.g., a power supply terminal from which a power supply voltage VDD is supplied) and a second terminal (e.g., a ground terminal from which a ground voltage GND is supplied). The power supply voltage monitor circuit 10 generates a monitored voltage Vm that results from dividing the power supply voltage VDD based on a resistance ratio between the resistors R1 and R2. In an example shown in FIG. 1, the resistor R1 is coupled to the power supply terminal and the resistor R2 is coupled to the ground terminal. The monitored voltage Vm is generated at a node between the resistor R1 and the resistor R2. The monitored voltage Vm has a voltage value resulting from dividing the power supply voltage VDD based on the resistance ratio between the resistors R1 and R2.

The monitored voltage Vm is input to a noninverting input terminal of the comparator 11 and a reference voltage VREF is input to an inverting input terminal thereof. The reference voltage VREF is a constant voltage that is generated by a reference voltage source which is not shown. The comparator 11 compares the monitored voltage Vm and the reference voltage VREF and outputs from its output terminal a voltage detection signal Vout for signifying that the power supply voltage VDD has exceeded a predetermined voltage value Vdet. Here, the predetermined voltage value Vdet is expressed by equation (2), given that a resistance value of the resistor R1 is denoted by R1, a resistance value of the resistor R2 is denoted by R2, and a voltage value of the monitored voltage Vm is denoted by Vm.

Vdet=Vm×(R1+R2)/R2 (2)

At a time instant when the monitored voltage Vm has exceeded the reference voltage VREF, the voltage detection signal that is output by the comparator 11 switches from a low level to a high level.

To the comparator 11, also, a boost signal BS is input that is output by the power supply voltage rising ramp detector circuit 13. During a period when the boost signal BS is enabled (e.g., high level), the comparator 11 is put in a high-speed operation mode with an increased operating current. During a period when the boost signal BS is disabled (e.g., low level), the comparator 11 is put in a low-speed operation mode with a decreased operating current. The comparator 11 operates at a high response speed to a voltage difference between the input signals in the high-speed operation mode and at a low response speed to a voltage difference between the input signals in the low-speed operation mode. Such switching can be accomplished as follows: a plurality of current sources are provided to supply an operating current to the comparator 11 and switching is performed between making the comparator 11 operate with a single current and making the comparator 11 operate with the current sources.

The resistance switching circuit 12 is equipped with a third resistor (e.g., resistor R3) which is coupled in parallel with the resistor R1 and a fourth resistor (e.g., resistor R4) which is coupled in parallel with the resistor R2 and makes the resistors R3 and R4 active during a period when the boost signal BS which will be described later is enabled (e.g., high level). That is, during a period when the resistance switching circuit 12 makes the resistors R3 and R4 active, a combined resistance of the resistors R1 and R3 is smaller and a combined resistance of the resistors R2 and R4 is also smaller. Here, it is preferable that a resistance ratio between the resistor R3 and the resistor R4 is substantially equal to the resistance ratio between the resistor R1 and the resistor R2. By making these two resistance ratios equal, it is possible to make the monitored voltage Vm constant in a state when the resistors R3 and R4 are active and in a state when the resistors R3 and R4 are inactive. It is also preferable that the resistance values of the resistors R3, R4 are smaller than the resistance values of the resistors R1, R2. This is because the smaller resistance values of the resistors R3, R4 can result in decreasing the combined resistance values when the resistors R3 and R4 are active and thus the voltage detector circuit is capable to respond to a steeper change of the power supply voltage VDD.

The resistance switching circuit 12 includes a PMOS transistor P1, an NMOS transistor N1, and an inverter 20, besides the resistors R3, R4. A source of the PMOS transistor P1 is coupled to a power supply terminal, its drain is coupled to one end of the resistor R3, and its gate is supplied with an inverted signal of the boost signal BS via the inverter 20. A source of the NMOS transistor N1 is coupled to a ground terminal, its drain is coupled to one end of the resistor R4, and its gate is supplied with the boost signal BS. The inverter 20 takes input of the boost signal BS and outputs the inverted signal of the boost signal BS.

That is, in the resistance switching circuit 12, during a period when the boost signal BS is enabled (e.g., high level), a low level signal is supplied to the gate of the PMOS transistor P1 and a high level signal is supplied to the gate of the NMOS transistor N1. In the resistance switching circuit 12, this makes the PMOS transistor P1 and the NMOS transistor N1 placed in a conductive state. And, this couples the one end of the resistor R3 to the power supply terminal and the one end of the resistor R4 to the ground terminal. That is, the resistors R3 and R4 become active, the resistor 3 is placed in a state that it is coupled in parallel with the resistor 1, and the resistor 4 is placed in a state that is coupled in parallel with the resistor 2.

On the other hand, in the resistance switching circuit 12, during a period when the boost signal BS is disabled (e.g., low level), a high level signal is supplied to the gate of the PMOS transistor P1 and a low level signal is supplied to the gate of the NMOS transistor N1. In the resistance switching circuit 12, this makes the PMOS transistor P1 and the NMOS transistor N1 placed in a non-conductive state. And, the one end of the resistor R3 is decoupled from the power supply terminal and the one end of the resistor R4 is decoupled from the ground terminal. That is, the resistors R3 and R4 become inactive and, in consequence, the power supply voltage monitor circuit 10 comprised of the resistors R1 and R2 is to operate singly.

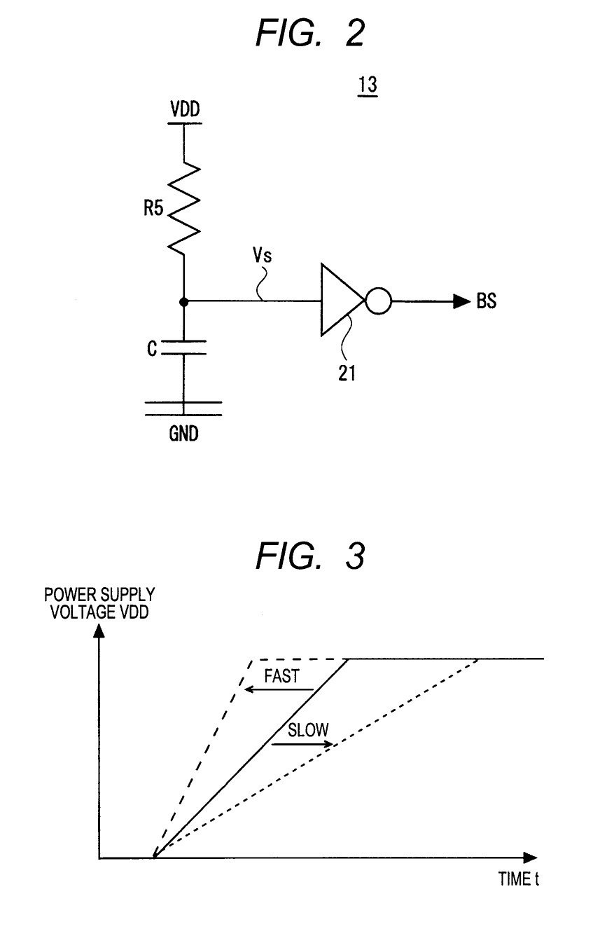

The power supply voltage rising ramp detector circuit 13 monitors the rising rapidity of the power supply voltage VDD and generates a boost signal which is enabled for a certain period, if the power supply voltage VDD rises faster than a preset rapidity to trigger operation switching. Now, detailed circuitry of the power supply voltage rising ramp detector circuit 13 is described. A detailed circuit diagram of the power supply voltage rising ramp detector circuit 13 is shown in FIG. 2.

As shown in FIG. 2, the power supply voltage rising ramp detector circuit 13 includes a fifth resistor (e.g., resistor R5), a capacitive element (e.g., a capacitor C), and an inverter 21. One end of the resistor R5 is coupled to a power supply terminal. One end of the capacitor C is coupled to a ground terminal and the other end of the capacitor C is coupled to the other end of the resistor R5. Here, at a node between the resistor R5 and the capacitor C, a rising ramp detected voltage Vs is generated. The inverter 21 takes input of the rising ramp detected voltage Vs and outputs a boost signal Bs. The inverter 21 switches between an enabled boost signal BS and a disabled boost signal BS, depending on the voltage level of the rising ramp detected voltage Vs. More specifically, the inverter 21 has a threshold voltage Vth that changes, following the power supply voltage VDD. The inverter 21 makes the boost signal enabled during a period when the rising ramp detected voltage Vs is smaller than the threshold voltage Vth.

Now, the rapidity to trigger operation switching in the power supply voltage rising ramp detector circuit 13 is described. In the power supply voltage rising ramp detector circuit 13, if the power supply voltage VDD rises faster than a time constant that is set by the resistor R5 and the capacitor C, the rising rapidity of the rising ramp detected voltage Vs is set slower than the rising rapidity of the power supply voltage VDD. On the other hand, in the power supply voltage rising ramp detector circuit 13, if the power supply voltage VDD rises slower than the time constant that is set by the resistor R5 and the capacitor C, the rising ramp detected voltage Vs is changed, following the change of the power supply voltage VDD. That is, the rapidity to trigger operation switching in the power supply voltage rising ramp detector circuit 13 is the time constant that is set by the resistor R5 and the capacitor C.

A graph representing a difference in the rising time of the power supply voltage that is applied to the voltage detector circuit is shown in FIG. 3. Referring to FIG. 3, the rapidity to trigger operation switching is described. In FIG. 3, when the power supply voltage rises as drawn by a solid line, the rate of the voltage change in the rising time (dVDD/dt) coincides with the time constant (1/(R5×C) set by the resistor R5 and the capacitor C. In the power supply voltage rising ramp detector circuit 13, the rate of change of the power supply voltage VDD drawn by the solid line in FIG. 3 is regarded as the reference (the rapidity to trigger operation switching). If the power supply voltage VDD rises at a rising rapidity faster than the reference (at a rate of change as drawn by a broken line), the power supply voltage rising ramp detector circuit 13 determines that the rising rapidity of the power supply voltage VDD is too fast and makes the boost signal BS enabled for a certain period. On the other hand, if the power supply voltage VDD rises at a rising rapidity slower than the reference (at a rate of change as drawn by a dotted line), the power supply voltage rising ramp detector circuit 13 determines that the rising rapidity of the power supply voltage VDD is too slow and makes the boost signal BS disabled.

Then, how the voltage detector circuit 1 operates is described. In the following, descriptions are provided for how the voltage detector circuit 1 operates in two cases where the rising rapidity of the power supply voltage VDD is faster or slower than the rapidity to trigger operation switching.

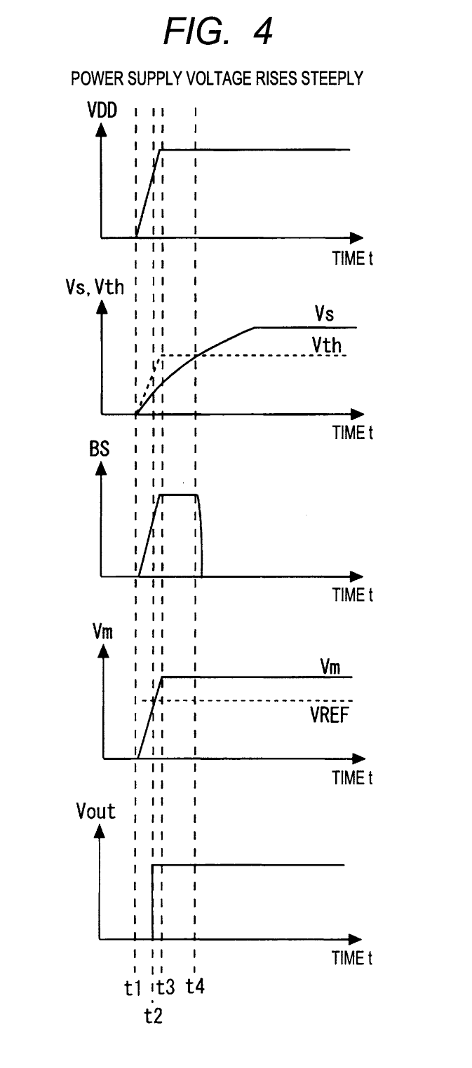

First, referring to FIG. 4, descriptions are provided for how the voltage detector circuit 1 operates, when the rising rapidity of the power supply voltage VDD is faster than the rapidity to trigger operation switching. In this case, the power supply voltage VDD rises during a period from time t1 to time t3. Then, the threshold voltage Vth of the inverter 21 rises following the rise of the power supply voltage VDD. Meanwhile, the rising rapidity of the rising ramp detected voltage Vs is delayed by the resistor R5 and the capacitor C in the power supply voltage rising ramp detector circuit 13. That is, the rising ramp detected voltage Vs rises behind the rise of the power supply voltage VDD. Consequently during a period from time t1 to time t4, the voltage level of the threshold voltage Vt of the inverter 21 is higher than the voltage level of the rising ramp detected voltage Vs. Hence, the output of the inverter 21 increases following the power supply voltage VDD during the period from time t1 to time t3 and remains at a high level during a period from t3 to t4. That is, in an example shown in FIG. 4, the boost signal BS that is output by the inverter 21 is enabled during a period from time t1 to time t4.

Due to that the boost signal BS is enabled during a period from time t1 to time t4, the PMOS transistor P1 and the NMOS transistor N1 are placed in a conductive state and the resistors R3 and R4 are made active in the resistance switching circuit 12. This couples the resistor R1 and the resistor 3 in parallel and couples the resistor R2 and the resistor R4 in parallel, which results in a decrease in the impedance of the node at which the monitored voltage Vm is generated. Then, the monitored voltage Vm is allowed to change following the rapid change of the power supply voltage VDD. In the example shown in FIG. 4, the monitored voltage Vm changes with the change of the power supply voltage VDD and becomes higher than the voltage value of the reference voltage VREF at time t2. At this time, the comparator 11 operates in the high-speed mode with an increased operating current, because the boost signal BS is enabled. Thus, the comparator 11 instantaneously responds to an event that the monitored voltage Vm has become larger than the reference voltage VREF and switches the voltage detection signal Vout from a low level to a high level.

Then, at time t4, the rising ramp detected voltage Vs becomes higher than the threshold voltage Vth of the inverter 21. This event that the monitored voltage Vm has become larger than the threshold voltage Vth of the inverter 21 causes a transition of the boost signal BS that is output by the inverter 21 to a disabled state. As a result of that the boost signal BS has become disabled, the PMOS transistor P1 and the NMOS transistor N1 are placed in a non-conductive state and the resistors R3 and R4 are made inactive in the resistance switching circuit 12. This shuts off a current flowing through the resistors R3 and R4. Then, in the voltage detector circuit 1, the monitored voltage Vm is to be generated only by a current flowing through the resistors R1 and R2. After time t4, the comparator 11 is to operate in the low-speed mode with a decreased operating current.

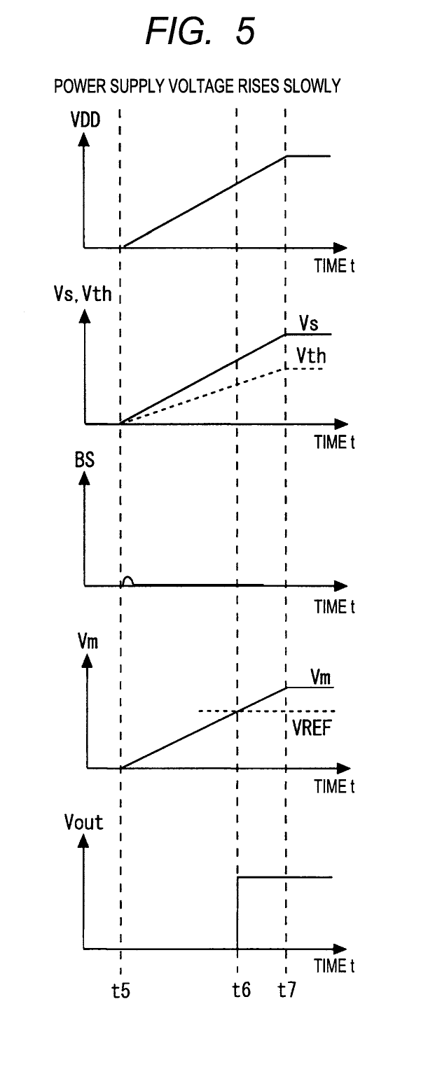

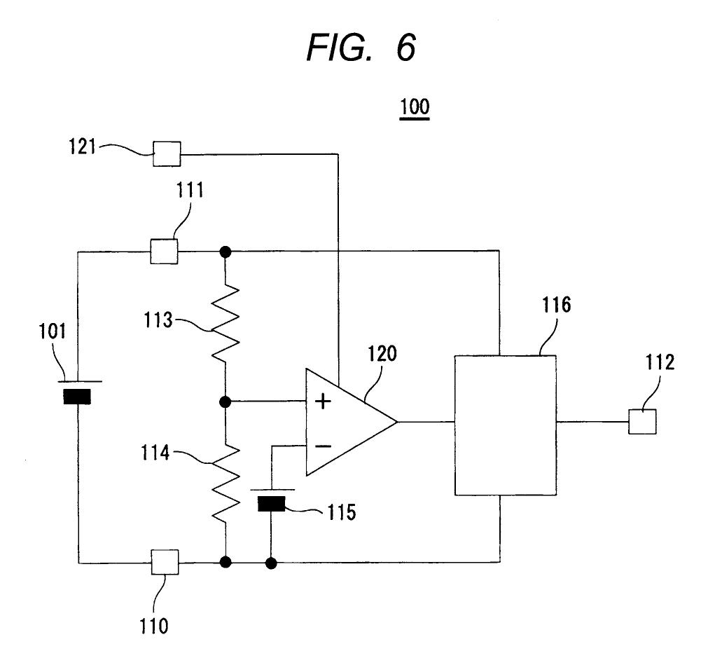

Then, referring to FIG. 5, descriptions are provided for how the voltage detector circuit 1 operates, when the rising rapidity of the power supply voltage VDD is slower than the rapidity to trigger operation switching. In this case, the power supply voltage VDD rises during a period from time t5 to time t7. Then, the threshold voltage Vth of the inverter 21 rises following the rise of the power supply voltage VDD. The rising rapidity of the rising ramp detected voltage Vs becomes a smaller rate of change than the time constant that is determined by the resistor R5 and the capacitor C in the power supply voltage rising ramp detector circuit 13. Hence, the rising ramp detected voltage Vs rises following the rise of the power supply voltage VDD. In an example shown in FIG. 5, during the rising period from time t5 to time t7, the voltage level of the threshold voltage Vth of the inverter 21 is always lower than the voltage level of the rising ramp detected voltage Vs. Hence, the output of the inverter 21 remains at a low level during the period the period from time t4 to time t7. That is, in the example shown in FIG. 5, the boost signal BS that is output by the inverter 21 remains disabled during the period from time t5 to time t7.

Due to that the boost signal BS is disabled during the period from time t5 to time t7, both the PMOS transistor P1 and the NMOS transistor N1 are placed in a non-conductive state and the resistors R3 and R4 are made inactive in the resistance switching circuit 12. Due to this, the impedance of the node at which the monitored voltage Vm is generated remains high. In addition, in the example shown in FIG. 5, because the power supply voltage VDD rises slowly, the rise of the monitored voltage Vm is not influenced by a time constant that is determined by the impedance and parasitic capacitance of the node at which the monitored voltage Vm is generated. That is, the monitored voltage Vm changes following the change of the power supply voltage VDD. And the monitor voltage Vm becomes higher than the voltage value of the reference voltage VREF at time t6. At this time, the comparator 11 operates in the low-speed mode with a decreased operating current, because the boost signal BS is disabled. However, because of a moderate change of the monitored voltage Vm, the comparator 11 can switch the voltage detection signal Vout from a low level to a high level virtually without a delay, in response to an event that the monitored voltage Vm has become larger than the reference voltage VREF.

Since the boost signal BS remains disabled even after time t7, the voltage detector circuit 1 generates the monitored voltage Vm only by a current flowing through the resistors R1 and R2 and makes the comparator 11 operate in the low-speed mode with a decreased operating current.

As noted from the above descriptions, the voltage detector circuit 1 pertaining to the present embodiment, if the rising rapidity of the power supply voltage VDD is faster than the predetermined rapidity to trigger operation switching, couples the resistors R1 and R3 in parallel and couples the resistors R2 and R4 in parallel. This results in a decrease in the impedance of the node at which the monitored voltage Vm is generated. It is thus possible to prevent the rising rapidity of the monitored voltage Vm from being delayed by the parasitic capacitance of the above node. In the voltage detector circuit 1, if the rising rapidity of the power supply voltage VDD is slower than the predetermined rapidity to trigger operation switching, the comparator 11 is supplied with an increased operating current so as to be able to switch the voltage level of the voltage detection signal Vout at a response speed enough to respond to a rapid change of the monitored voltage Vm. That is, in the voltage detector circuit 1 pertaining to the present embodiment, it is possible to sufficiently follow a rapid change of the power supply voltage VDD and switch the voltage level of the voltage detection signal Vout.

Further, the voltage detector circuit 1 pertaining to the present embodiment, even if the rising rapidity of the power supply voltage VDD is fast, after the rise of the power supply voltage VDD, makes the resistors R3 and R4 inactive, thus cutting down the current flowing thorough the resistors, and reduces the consumption current of the comparator 11. Thereby, it is possible to reduce the consumption current after the rise of the power supply voltage VDD.

Besides, the voltage detector circuit 1 pertaining to the present embodiment, if the rising rapidity of the power supply voltage VDD is slow, makes the resistors R3 and R4 inactive and makes the comparator 11 operate in the low-speed mode with a decreased operating current. In the case that the rising rapidity of the power supply voltage VDD is small, the monitored voltage Vm changes following the change of the power supply voltage VDD without being influenced by the time constant of the node at which the monitored voltage Vm is generated. Hence, in such case, there is no effect on the speed of detecting the voltage level of the power supply voltage VDD, even in the operation mode in which the consumption current of the resistors R3, R4 and the comparator 11 is reduced.

Moreover, in the voltage detector circuit 1 pertaining to the present embodiment, the boost signal BS for switching the operation mode of the comparator 11 is generated by the power supply voltage rising ramp detector circuit 13 which is formed in the same semiconductor device. Thus, there is no need to externally supply a signal for switching the operation mode of the comparator 11. In a case that a signal for switching the operation mode of the comparator 11 is externally supplied, the voltage level of the power supply voltage VDD needs to be monitored externally. In view hereof, by generating the boost signal BS for switching the operation mode of the comparator 11 by the power supply voltage rising ramp detector circuit 13 which is provided in the same semiconductor device, it is possible to realize reducing the number of terminals of the semiconductor device and enhanced controllability in the voltage detector circuit 1.

Although the invention has been described above in connection with the embodiment thereof, it will be appreciated by those skilled in the art that that embodiment are provided solely for illustrating the invention, and should not be relied upon to construe the appended claims in a limiting sense.

Further, it is noted that, notwithstanding any claim amendments made hereafter, applicant's intent is to encompass equivalents all claim elements, even if amended later during prosecution.

What is claimed is:

1. A voltage detector circuit comprising:
a power supply voltage monitor that is equipped with first and second resistors coupled between a first terminal and a second terminal, and that generates a monitored voltage resulting from dividing a power supply voltage, which is supplied from the first terminal, based on a resistance ratio between the first and second resistors;
a power supply voltage rising ramp detector that monitors the rising rapidity of the power supply voltage, and that generates a boost signal which is enabled for a certain period, if the power supply voltage rises faster than a preset rapidity to trigger operation switching;
a resistance switching circuit that is equipped with a third resistor which is coupled in parallel with the first resistor and a fourth resistor which is coupled in parallel with the second resistor, and that makes the third and fourth resistors active during a period when the boost signal is enabled; and
a comparator that compares the monitored voltage with a reference voltage, and that outputs a voltage detection signal indicating that the power supply voltage has exceeded a predetermined voltage value.

2. The voltage detector circuit according to claim 1,
wherein a resistance ratio between the third and fourth resistors is substantially equal to the resistance ratio between the first and second resistors.

3. The voltage detector circuit according to claim 1,
wherein the third and fourth resistors have resistance values smaller than the first and second resistors.

4. The voltage detector circuit according to claim 1,
wherein the comparator is supplied with an increased operating current during a period when the boost signal is enabled.

5. The voltage detector circuit according to claim 1,
wherein the resistance switching circuit comprises:
a first transistor which is coupled between the third resistor and a power supply terminal; and
a second transistor which is coupled between the fourth resistor and a ground terminal, and
wherein the first and second transistors are placed in a conductive state during a period when the boost signal is enabled.

6. The voltage detector circuit according to claim 1,
wherein the power supply voltage rising ramp detector comprises:
a fifth resistor, one end of which is coupled to the first terminal;
a capacitive element, one end of which is coupled to the second terminal and the other end of which is coupled to the other end of the fifth resistor; and
an inverter that makes the boost signal enabled during a period when a rising ramp detected voltage which is generated at a node between the fifth resistor and the capacitive element is smaller than a threshold voltage which changes following the power supply voltage.

7. The voltage detector circuit according to claim 1,
wherein the first terminal is a power supply terminal supplying the power supply voltage, and
wherein the second terminal is a ground terminal supplying a ground voltage.
